(19) United States
(12) Patent Application Publication
(10) Pub. No.: US 2026/0088760 A1
(43) Pub. Date: Mar. 26, 2026

(54) CRYSTAL ELEMENT, QUARTZ CRYSTAL DEVICE USING THE SAME, AND INTERMEDIATE WAFER FOR QUARTZ CRYSTAL DEVICE, AND METHOD FOR MANUFACTURING CRYSTAL ELEMENT

(71) Applicant: NIHON DEMPA KOGYO CO., LTD., Tokyo (JP)

(72) Inventor: Hiroyuki SASAKI, Saitama (JP)

(73) Assignee: NIHON DEMPA KOGYO CO., LTD., Tokyo (JP)

(21) Appl. No.: 19/333,247

(22) Filed: Sep. 18, 2025

(30) Foreign Application Priority Data
Sep. 20, 2024 (JP) 2024-164352
Feb. 20, 2025 (JP) 2025-025764
Jul. 17, 2025 (JP) 2025-120153

(51) Int. Cl. H03B 5/32; H03B 5/04; H03H 3/02; H03H 9/19

(52) U.S. Cl. CPC H03B 5/32; H03B 5/04; H03H 3/02; H03H 9/19; H03B 2200/0018

(57) ABSTRACT

A crystal element having a first axis-second axis plane specified by a first axis derived from an X-axis and a second axis derived from a Z-axis as a principal surface and having a third axis derived from a Y-axis as a thickness direction. The first side surface of the first axis and the second side surface of the first axis are each constituted of a crystal face derived from the crystal and a plane that has a contour parallel to a normal line of the principal surface. The first side surface of the second axis and the second side surface of the second axis are each constituted of a crystal face derived from the crystal and a plane that has a contour parallel to a normal line of the principal surface, or constituted of a crystal face derived from the crystal non-parallel to the normal line of the principal surface.

### CROSS-REFERENCE TO RELATED APPLICATIONS

This application is based on and claims priority under 35 U.S.C. § 119 to Japanese Patent Application Nos. 2024-164352, filed on Sep. 20, 2024, 2025-025764, filed on Feb. 20, 2025, and 2025-120153, filed on Jul. 17, 2025, the entire content of which is incorporated herein by reference.

### TECHNICAL FIELD

This disclosure relates to a crystal element suitable for using in manufacturing a quartz crystal device, such as a crystal unit, a crystal unit with a temperature sensor, and a crystal controlled oscillator (also including a crystal controlled oscillator with a temperature compensation function), a quartz crystal device, and an intermediate wafer suitable to be used in manufacturing the quartz crystal device, and a method for manufacturing the crystal element.

### DESCRIPTION OF THE RELATED ART

In association with a reduced size and a higher frequency of a communication device, a quartz crystal device as a frequency reference source of the communication device is increasingly required to have a reduced size and a higher frequency. Accordingly, a crystal element that constitutes the quartz crystal device is also desired to be one with a reduced and thin size. Therefore, an AT-cut crystal element is widely manufactured using a photolithography technique and a wet etching technique. One example thereof is disclosed in, for example, paragraphs 42 to 48 and FIG. 3 in, for example, Japanese Unexamined Patent Application Publication No. 2014-27505.

In the crystal element disclosed in Japanese Unexamined Patent Application Publication No. 2014-27505, at least one of side surfaces of the side surfaces at both ends along an X-axis of a crystal includes at least four planes, and two planes constituting an end portion on the side surface form an obtuse angle (for example, claim 6 and claim 7 in Japanese Unexamined Patent Application Publication No. 2014-27505).

The photolithography technique and the wet etching technique are certainly effective techniques for achieving a reduced size and a higher frequency of a crystal element. However, in the case of these techniques, an outer shape of the crystal element may have a shape that impairs characteristics of a quartz crystal device in some cases due to anisotropy with respect to wet etching of crystallographic axes of a crystal. Specifically, side surfaces of the crystal element formed by the photolithography technique and the wet etching technique have a shape having an inclined surface inclining with respect to a principal surface of the crystal element and protruding outward of the crystal element due to crystallinity of the crystal as described in Japanese Unexamined Patent Application Publication No. 2014-27505. On the other hand, a region used as a vibrating region of the crystal element is a portion through which the principal surfaces are opposed in a parallel manner, and therefore, the portion having the inclined surface of the crystal element does not function as the vibrating region. Accordingly, the longer a dimension parallel to the principal surface of the crystal element of a portion where the side surface includes many inclined surfaces is, the narrower the vibrating region becomes, which is unpreferable in terms of freedom of design of the crystal element and improving characteristics of the quartz crystal device. As the size reduction of the quartz crystal device proceeds, the crystal element itself becomes smaller and a proportion of the inclined surface occupying the crystal element increases, which worsens the above-described problem.

A need thus exists for a crystal element, a quartz crystal device using the same, and an intermediate wafer for the quartz crystal device, and a method for manufacturing the crystal element which are not susceptible to the drawback mentioned above.

### SUMMARY

According to an aspect of this disclosure, there is provided a crystal element in a quadrilateral shape in plan view having a first axis-second axis plane specified by a first axis derived from an X-axis of a crystal and a second axis derived from a Z-axis of the crystal as a principal surface and having a third axis derived from a Y-axis of the crystal as a thickness direction. When one side of side surfaces intersecting with the first axis of the crystal element is defined as a first side surface of the first axis and another side is defined as a second side surface of the first axis, and one side of side surfaces intersecting with the second axis of the crystal element is defined as a first side surface of the second axis and another side is defined as a second side surface of the second axis. The first side surface of the first axis and the second side surface of the first axis are each constituted of a crystal face derived from the crystal and a plane that has a contour parallel to a normal line of the principal surface. The first side surface of the second axis and the second side surface of the second axis are each constituted of a crystal face derived from the crystal and a plane that has a contour parallel to a normal line of the principal surface, or constituted of a crystal face derived from the crystal non-parallel to the normal line of the principal surface.

Note that the plane that has the contour parallel to the normal line of the principal surface referred to in this disclosure is a plane having a contour positively parallel to or a surface having a contour approximately parallel to the normal line when the contour along the normal line of the plane is viewed. In other words, the plane that has the contour parallel to the normal line of the principal surface is that the plane is a plane positively perpendicular to or a plane approximately perpendicular to the principal surface (hereinafter, they may be referred to as a vertical plane). The vertical plane referred to in this disclosure may be any of the case of a non-crystal face, the case of a crystal face, or the case of a plane in which the non-crystal face and the crystal face are mixed.

The crystal face and the non-crystal face referred to in this disclosure may include minute unevenness, for example, unevenness with a height difference of, for example, a several nm to approximately 1 μm unevenness, preferably, several 10 nm to approximately 1 μm unevenness on the surface. This is because unnecessary vibration for the main vibration of the crystal element can be expected to be reducible.

Upon executing this first disclosure, the crystal element of the first disclosure is typically a crystal element that vibrates in a thickness-shear mode, and is, for example, an AT-cut crystal element, what is called, a twice-rotated crystal element typified by an SC-cut vibrating piece. When the crystal element is the AT-cut crystal element, the first axis is the X-axis of the crystal, the second axis is the Z′-axis of the crystal, and the third axis is the Y′-axis of the crystal. Here, the Z′-axis and the Y′-axis are, as is well known, angles displaced from the Z-axis of the crystal and the Y-axis of the crystal corresponding to the cut angle from a crystal bar of the AT-cut crystal element.

The first disclosure is applicable to a crystal element having a first axis-second axis plane of a first axis derived from the X-axis of the crystal and a second axis derived from the Y-axis of the crystal as the principal surface and having a third axis derived from the Z-axis of the crystal as a thickness direction. For example, the first disclosure is also applicable to a contour mode crystal element, such as of a GT-cut, a flexure mode crystal element, such as a tuning-fork type crystal unit, or the like.

A disclosure of a quartz crystal device, which is a second disclosure of this application, includes a quartz-crystal vibrating piece including the crystal element according to the first disclosure and excitation electrodes provided on front and back principal surfaces of this crystal element, and a container containing this quartz-crystal vibrating piece.

Note that, the quartz crystal device referred to in this second disclosure is typically a crystal unit, a crystal unit with a temperature sensor, or a crystal controlled oscillator (also including a crystal controlled oscillator having a temperature compensation function).

A disclosure of an intermediate wafer for a quartz crystal device, which is a third disclosure of this application, is made of a crystal wafer including a plurality of quartz-crystal vibrating pieces including the crystal element according to the first disclosure and excitation electrodes provided on front and back of this crystal element in a matrix.

When the crystal element according to the above-described first disclosure is manufactured, it is preferred to manufacture in the following method that corresponds to a fourth disclosure of this application.

That is, it is preferred to perform steps including a step of preparing a crystal wafer, a step of forming a crystallinity lost region in a thickness direction of the crystal wafer by a laser light, preferably an ultrashort pulse laser irradiating an outer edge planned portion along the outer edge planned portion of the crystal element of this crystal wafer, and a step of forming an outer shape of the crystal element by immersing the crystal wafer in which the crystallinity lost region is formed in an etchant for wet etching, for example, a hydrofluoric acid-based etchant, and removing a region including the outer edge region of the crystal wafer and penetrating the crystal wafer.

Furthermore, when this manufacturing method is executed, it is preferred that a time of immersing the crystal wafer in the etchant is adjusted to control a dimension (a dimension denoted with t1 in FIG. 1A and the like) of the vertical plane in a thickness direction of the crystal wafer. More specifically, it is preferred that a time of immersing the crystal wafer in the etchant is adjusted to control proportions of the dimension (the dimension denoted with t1 in FIG. 1A and the like) of the vertical plane in the thickness direction of the crystal wafer and the crystal face derived from the crystal connected to the vertical plane.

With the crystal element according to the first disclosure of this application, each of the first side surface of the first axis and the second side surface of the first axis, or depending on the case, the first side surface and the second side surface of the second axis are constituted of the crystal face derived from the crystal and the vertical plane as the plane having the contour parallel to the normal line of the principal surface of the crystal element. Accordingly, compared with the case where these side surfaces are constituted only of the inclined surfaces derived from the crystal faces of the crystal, the proportion of the inclined surfaces occupying the side surfaces is reducible, and therefore, the area (the area usable as the vibrating region) of the crystal element where both the principal surfaces are opposed reducing in size can be reduced compared with the conventional case. When the quartz-crystal vibrating piece has a wide vibrating region, generally there are advantages that the electrical performance of the quartz-crystal vibrating piece is more likely to be improved, the design freedom of the quartz-crystal vibrating piece is enhanced, and the like, and thus, the above-described advantages are easily obtained with the present disclosure. Accordingly, a crystal element having a novel shape suitable to be used in manufacturing the quartz crystal device is providable.

With the disclosure of the quartz crystal device as the second disclosure of this application, a quartz crystal device with high characteristics compared with the conventional ones is achieved.

With the intermediate wafer for the quartz crystal device as the third disclosure of this application, a quartz crystal device with high characteristics compared with the conventional ones is manufacturable in mass production.

With the method for manufacturing the crystal element as the fourth disclosure of this application, the crystal element of the first disclosure is easily manufacturable.

### BRIEF DESCRIPTION OF THE DRAWINGS

The foregoing and additional features and characteristics of this disclosure will become more apparent from the following detailed description considered with reference to the accompanying drawings, wherein:

FIG. 1A to FIG. 1C are drawings for describing a crystal element 10 of an embodiment;

FIG. 2A to FIG. 2C are drawings for describing reasons of asserting angles θa and θb, and the like referred to in this disclosure;

FIG. 3 is a drawing for describing a structural example of both side end surfaces along a Z′-axis different from that of the crystal element 10 of the embodiment;

FIG. 4 is a drawing (a SEM photograph) observing a +X-plane, −X-plane, and a Z′-plane of the crystal element 10 of the embodiment;

FIG. 5A and FIG. 5B are drawings for describing a crystal element 100 of Comparative Example;

FIG. 6A and FIG. 6B are drawings for describing a quartz crystal device 20 of the embodiment;

FIG. 7A and FIG. 7B are drawings for describing a quartz crystal device 30 of another embodiment;

FIG. 8A to FIG. 8C are drawings for describing respective electrical characteristic examples of the quartz crystal device 20 of the embodiment and a quartz crystal device of Comparative Example;

FIG. 9A and FIG. 9B are drawings for describing preferred dimension examples of the crystal element 10 having an oscillation frequency of 76.8 MHz; and

FIG. 10A to FIG. 10D are drawings for describing an embodiment of a manufacturing method as a fourth disclosure and drawings for describing an intermediate wafer 50x of an embodiment of a third disclosure.

### DETAILED DESCRIPTION

The following describes embodiments of respective disclosures of this application with reference to the drawings. Each drawing used in the description is merely illustrated schematically so as to make these disclosures understandable. In each drawing used in the description, the same reference numerals designate similar elements, and therefore such elements may not be further elaborated here. Shapes, materials, and manufacturing method examples, and the like described in the following embodiments are merely preferable examples within the scope of this disclosure. Therefore, this disclosure is not limited to only the following embodiments.

### 1. Crystal Element of Embodiment

### 1-1. Structure Outline

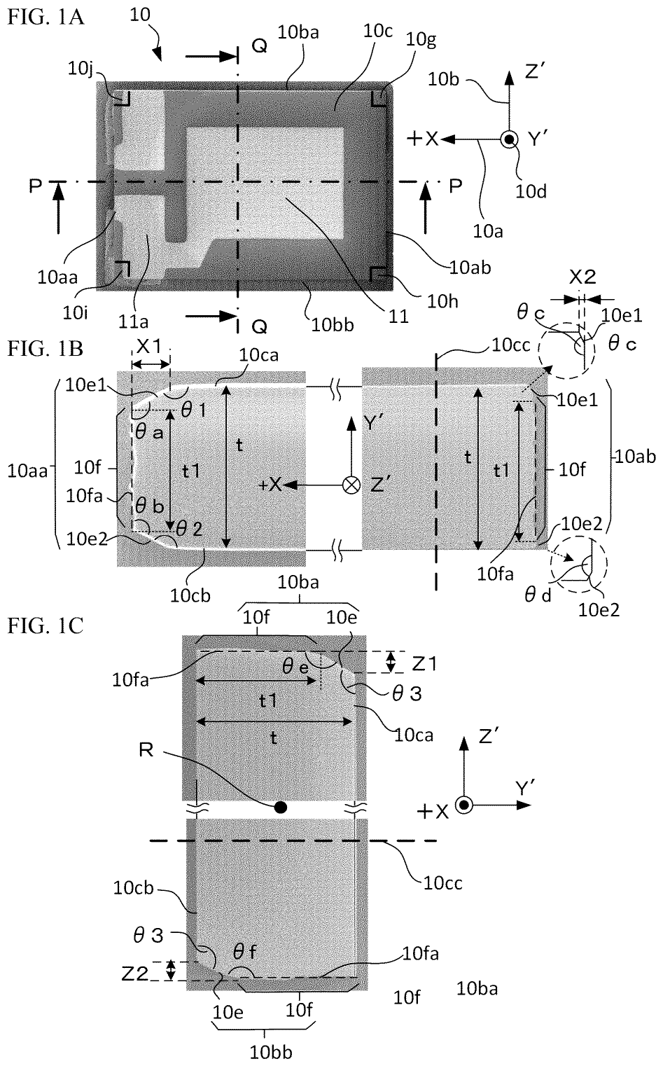

With reference to FIG. 1A to FIG. 1C, a crystal element 10 according to an embodiment will be described. Here, FIG. 1A is a top view of the crystal element 10, FIG. 1B is a sectional drawing of the crystal element 10 taken along the line IB-IB in FIG. 1A, and FIG. 1C is a sectional drawing of the crystal element 10 taken along the line IC-IC in FIG. 1A. However, the crystal element 10 in the case of FIG. 1A is illustrated in a state of a quartz-crystal vibrating piece including excitation electrodes 11 on front and back principal surfaces 10c. In FIG. 1A, the reference numeral 11a denotes an extraction electrode extracted to one side of the crystal element 10 from the excitation electrode 11. Any of FIG. 1A to FIG. 1C is a drawing using an electron microscope (SEM) photograph of the crystal element 10 of the embodiment. Coordinate axes X, Y′, Z′ illustrated in FIG. 1A indicate axes derived from crystallographic axes X, Y, Z-axes of the crystal. Note that dashes on a Z′-axis and a Y′-axis mean axes displaced due to the cut angle of the AT-cut from the Z-axis and the Y-axis of the crystal, which is caused by the crystal element 10 used in this embodiment being an AT-cut crystal element.

The crystal element 10 of the embodiment is a crystal element in a quadrilateral shape in plan view having first axis-second axis planes specified by a first axis 10a derived from the X-axis of the crystal and a second axis 10b derived from the Z-axis of the crystal as principal surfaces 10ca and 10cb, and a third axis 10d derived from the Y-axis of the crystal as a thickness direction. Specifically, the crystal element 10 of the embodiment, in this case, is an AT-cut crystal element having a planar shape with an X-axis direction of the crystal being a long side and a Z′-axis direction of the crystal being a short side in a rectangular shape. Accordingly, the first axis 10a is the X-axis of the crystal, the second axis 10b is the Z′-axis of the crystal, and the third axis 10d is the Y′-axis of the crystal.

In this crystal element 10, the two principal surfaces 10ca and 10cb are surfaces parallel to one another, and are regions where the crystal element 10 has a thickness t.

When one side surface (in this case, a +X-side side surface) intersecting with the first axis (in this case, the X-axis of the crystal) of the crystal element 10 is defined as a first side surface 10aa of the first axis and another side surface (in this case, −X-side side surface) is defined as a second side surface 10ab of the first axis, and one side surface intersecting with the second axis (the Z′-axis of the crystal) of the crystal element is defined as a first side surface 10ba of the second axis and another is defined as a second side surface 10bb of the second axis, this crystal element 10 has the respective side surfaces in the following configurations.

That is, as illustrated in FIG. 1B, while the details will be described below, each of the first side surface 10aa of the first axis and the second side surface 10ab of the first axis is constituted of crystal faces 10e1 and 10e2 derived from the crystal and a plane 10f (also referred to as the vertical plane 10f) that connects to the crystal faces 10e1 and 10e2 between the crystal faces 10e1 and 10e2 and has a contour 10fa parallel to a normal line 10cc of the principal surface.

As illustrated in FIG. 1C, while the details will be described below, each of the first side surface 10ba of the second axis and the second side surface 10bb of the second axis is constituted of a crystal face 10e derived from the crystal and the plane 10f (also referred to as the vertical plane 10f) that connects to the crystal face 10e and has the contour 10fa parallel to the normal line 10cc of the principal surface in this embodiment. The following describes the respective side surfaces 10aa, 10ab, 10ba, and 10bb in detail.

### 1-2. Side Surface on +X-Side, Side Surface of −X-Side of Crystal Element

First, with reference to FIG. 1B, structures of the first side surface 10aa of the first axis and the second side surface 10ab of the first axis will be described.

### 1-2-1. First Side Surface 10Aa of First Axis (Side Surface on +X-Side)

The first side surface 10aa of the first axis is a side surface on the +X-side of the crystal of the two side surfaces intersecting with the X-axis of the crystal in this case. This first side surface 10aa of the first axis is constituted of the crystal face 10e1 (the first crystal face 10e1) in contact with the principal surface 10ca on one side of the crystal element 10, the crystal face 10e2 (the second crystal face 10e2) in contact with the principal surface 10cb on the other side of the crystal element 10, the plane 10f (also referred to as the vertical plane 10f) that is present between these two crystal faces 10e1 and 10e2 and has the contour 10fa parallel to the normal line 10cc of the principal surface, as illustrated on the left side in FIG. 1B.

On the cross-sectional surface taken along an X-Y′ plane determined by the X-axis and the Y′-axis of the crystal element 10, when, at a plus-side end portion of the X-axis, an angle formed by the vertical plane 10f and the first crystal face 10e1 connected to the vertical plane 10f is defined as θa and an angle formed by the vertical plane 10f and the second crystal face 10e2 connected to the vertical plane 10f is defined as θb, θa has an angle in the range of 90°<θa≤130°, and more specifically 114°≤θa≤130°, and θb has an angle in the range of 90°<θb≤130°, and more specifically 114°≤θb≤130°. Note that any one of the case θa=θb or the case θa≠θb are possible.

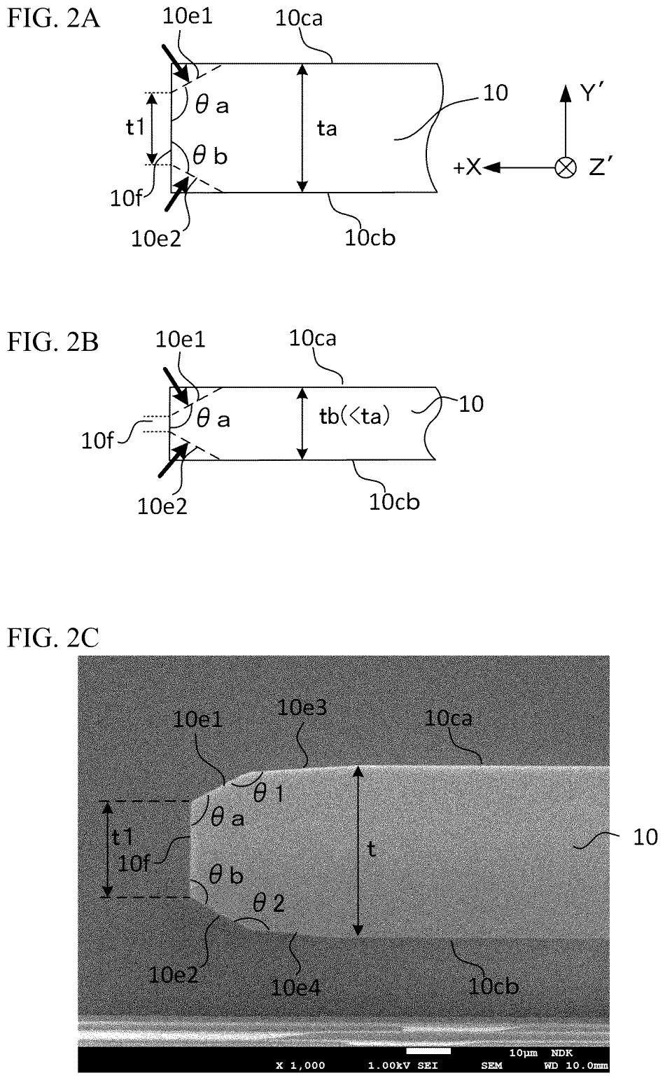

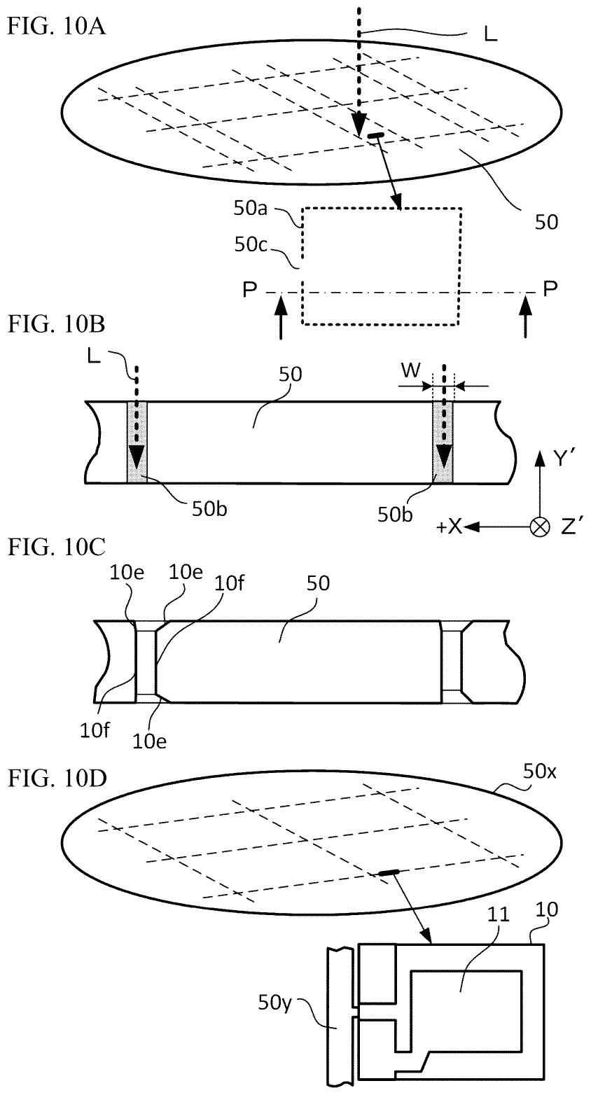

The reasons the angles θa and θb are preferred to be in the above-described ranges are as follows. This description is described with reference to FIG. 2A and FIG. 2B. Here, FIG. 2A illustrates an image when the AT-cut crystal element 10 having a thickness ta processed by a manufacturing method using a laser and wet etching described with reference to FIG. 10A to FIG. 10D described below in a sectional drawing taken along the X-Y′ plane of the crystal element 10. FIG. 2B illustrates an image when the AT-cut crystal element 10 having a thickness tb (<ta) processed by the manufacturing method using the laser and the wet etching described with reference to FIG. 10A to FIG. 10D described below in a sectional drawing taken along the X-Y′ plane of the crystal element 10.

In both the case where the thickness of the crystal element 10 is ta and the case where tb (<ta), as the wet etching proceeds, etching in the thickness direction (a Y′ direction) of the crystal element 10 proceeds. In addition, during this wet etching, it has been proven in an experiment by the inventor of this application that the first crystal face 10e1 and the second crystal face 10e2 are generated, and the first crystal face 10e1 and the second crystal face 10e2 grow toward a center side of the crystal element 10 while mostly maintaining the angles θa and θb with respect to the vertical plane 10f. Here, the meaning of mostly maintaining the angles θa and θb means that, while slight differences are generated by a depth in the thickness direction of the crystal element in a crystallinity lost region caused by laser irradiation, which will be described with reference to FIG. 10A to FIG. 10D, a width in a direction along the principal surface of the crystal element, a wet etching time, conditions of an etching resistant mask during the wet etching, and the like, θa and θb fall within the above-described ranges as the wet etching proceeds on a certain crystal face in the crystal faces of the crystal in a standard range. The above-described ranges for the angles θa and θb are considered to be valid also from the following experimental result by the inventor of this application.

That is, θa and θb have been proven to fall within the range of 114° to 130° in the case where the crystal element 10 with an initial thickness of 60 μm is used for an example of FIG. 2A and undergoes the laser irradiation and the etching, and in both the cases of the respective crystal elements in the experiments where the crystal element 10 with an initial thickness of 40 μm and the crystal element 10 with an initial thickness of an initial thickness of 26 μm are used for examples of FIG. 2B and undergo the laser irradiation and the etching. However, when the thickness of the crystal element 10 is thin (that is, when the thickness is tb), the first crystal face 10e1 and the second crystal face 10e2 quickly join compared to the case where the thickness is ta, and therefore, the vertical plane 10f is quickly lost to form a beak-shaped end surface, thus leaving only an inclined surface.

By taking these into consideration, for the end surface on the +X-side, the structure having the vertical plane 10f and including the first crystal face 10e1 and the second crystal face 10e2 intersecting with this vertical plane 10f at the angles θa and θb is considered to be an end surface structure that can achieve expansion of the vibrating region.

The relation of each of the first crystal face 10e1 and the second crystal face 10e2 with the principal surface of the crystal element has been proven to be as follows from the above-described experiment by the inventor. That is, the angle θ1 formed by the first crystal face 10e1 and the principal surface 10ca and the angle θ2 formed by the second crystal face 10e2 and the principal surface 10cb are in a range of 143° to 159°. In the example in FIG. 1B, it is 144°.

Note that the end portion on the +X-side of the crystal of the crystal element 10 may have a case where a third crystal face 10e3 is generated between the first crystal face 10e1 and the principal surface 10ca on one side and a fourth crystal face 10e4 is generated between the second crystal face 10e2 and the principal surface 10cb on the other side as illustrated in the SEM photograph in FIG. 2C when the wet etching time is increased. Also in this case, the distal end of the end portion on the +X-side of the crystal of the crystal element 10 is the vertical plane 10f, and the structure that can achieve ensuring the vibrating region referred to in this disclosure is provided.

As illustrated in FIG. 1B, when the thickness of a portion (the thickness in the Y′-direction in FIG. 1B) between the principal surfaces 10ca and 10cb of the crystal element 10 are opposed is defined as t, and the dimension of the vertical plane 10f in the Y′-direction is defined as t1, the larger t1/t is, the more preferable it is, as the proportion of the side surface coming perpendicular to the principal surface is increased, thereby facilitating ensuring the vibrating region. t1/t is not limited to this, and may be 30% or more, is preferably 50% or more, and is more preferably 70% or more. In the case of the drawing on the left in FIG. 1B, t1/t is approximately 74%, and in the case of the FIG. 2C, t1/t is approximately 56%.

### 1-2-2. Second Side Surface 10ab of First Axis (Side Surface on −X-side)

On the other hand, the second side surface 10ab of the first axis is a side surface on the −X-side of the crystal of the two side surfaces intersecting with the X-axis of the crystal in this case. This second side surface 10ab of the first axis is constituted of the first crystal face 10e1 in contact with the principal surface 10ca on one side of the crystal element 10, the second crystal face 10e2 in contact with the principal surface 10cb on the other side of the crystal element 10, and the plane 10f (also referred to as the vertical plane 10f) that is present between these first crystal face 10e1 and second crystal face 10e2 and in contact with these crystal faces, and has the contour 10fa parallel to a normal line 10cc, as illustrated on the right side in FIG. 1B.

On the cross-sectional surface taken along the X-Y′ plane determined by the X-axis and the Y′-axis of the crystal element 10, when, at a minus-side end portion of the X-axis, an angle formed by the vertical plane 10f and the first crystal face 10e1 connected to the vertical plane 10f is defined as θc and an angle formed by the vertical plane 10f and the second crystal face 10e2 connected to the vertical plane 10f is defined as θd, θc has an angle in the range of 90°<θc≤158°, and more specifically 149°≤θc≤158°, and θd has an angle in the range of 90°<θd≤158°, and more specifically 149≤θd≤158°. However, any one of the case θc=θd or the case θc≠θd is possible.

When the thickness of a portion (the thickness in the Y′-direction in FIG. 1B) between the principal surfaces 10ca and 10cb of the crystal element 10 are opposed is defined as t, and the dimension of the vertical plane 10f in the Y′-direction is defined as t1, while t1/t is not limited to this, for example, t1/t may be 30% or more, is preferably 50% or more, and is more preferably 70% or more. In the case of this embodiment, t1/t is approximately 90% on the end surface on the −X-side.

Note that the reason the angles θc and θd are preferred to be in 149°≤θc≤158° and 149°≤θd≤158° is the same as the reason of claiming the ranges of the angles θa and θb on the +X-side end surface described above. That is, they are the angles proven by the experiment by the inventor of this application.

Note that the reason the angles θa and θb on the +X-side end surface and the angles θc and θd on the −X-side end surface are different, and also, the reason t1/t on the +X-side end surface and t1/t on the −X-side end surface are different are because the etching rate for wet etching the crystal is +X>−X.

### 1-3. Both End Side Surfaces Along Z′-Direction of Crystal Element

Next, with reference to FIG. 1C, the first side surface 10ba of the second axis and the second side surface 10bb of the second axis are described.

The first side surface 10ba of the second axis is, in this case, a side surface on one side of the two side surfaces intersecting with the Z′-axis of the crystal, and the second side surface 10bb of the second axis is, in this case, a side surface on the other side of the two side surfaces intersecting with the Z′-axis of the crystal.

The first side surface 10ba of the second axis and the second side surface 10bb of the second axis are each constituted of the crystal face 10e derived from the crystal and the plane 10f (also referred to as the vertical plane 10f) having the contour 10fa parallel to the normal line 10cc of the principal surface in the case of this embodiment.

When an angle formed by the crystal face 10e and the vertical plane 10f on the first side surface 10ba of the second axis is defined as θe and an angle formed by the crystal face 10e and the vertical plane 10f on the second side surface 10bb of the second axis is defined as θf, θe has an angle in the range of 90°<θe≤162°, and more specifically 141°≤θe≤162°, and θf has an angle in the range of 90°<θf≤162°, and more specifically 141°≤θf≤162°. However, any one of the case θe=θf or the case θe θf is possible. Typically, θe=θf.

Note that the reason the angles θe and θf are preferred to be in the ranges of 141° ≤θe≤162° and 141°≤θf≤162° is the same as the reason of claiming the ranges of the angles θa and θb on the +X-side end surface described above, and that is because the angles θe and θf are proven to fall within the range of 141° to 162° in the experiment by the inventor of this application.

On both the ends along the Z′-axis, the thickness of a portion (the thickness in the Y′-direction in FIG. 1C) between the principal surfaces 10ca and 10cb of the crystal element 10 are opposed is defined as t, and the dimension of the vertical plane 10f in the Y′-direction is defined as t1, the larger t1/t is, the more preferable it is, as the proportion of the side surface coming perpendicular to the principal surface is increased, thereby facilitating ensuring the vibrating region. t1/t is not limited to this, and, for example, may be 30% or more, is preferably 50% or more, and is more preferably 70% or more. In the case of this embodiment, t1/t is approximately 74%.

On both the end surfaces of the crystal element 10 along the Z′-axis, the crystal face 10e and the principal surface 10ca (10cb) intersect at an angle θ3. The angle θ3 is proven to be a range of 115 to 145 degrees according to the above-described experiment by the inventor of this application. The respective crystal faces 10e of the first side surface 10ba as the side surface on one side of the crystal element 10 along the Z′-axis and the second side surface 10bb as the side surface on the other side schematically have point symmetry relations with a center point R (see FIG. 1C) of the crystal element 10.

The following remarkable facts are found. That is, in the case of the crystal element 10 according to this disclosure, the respective crystal faces 10e on the first side surface 10ba and the second side surface 10bb along the Z′-direction are generated on the principal surface side on the opposite side of the principal surface on the side an m-plane of the crystal may be generated of the two principal surfaces of the crystal element 10. These respective crystal faces 10e are considered to be surfaces affected by an r-plane (small r-plane) as one of the crystal faces of the crystal. That is, in the case of a crystal element 100 in Comparative Example described with reference to FIG. 5A and FIG. 5B later, a crystal face 100e is an m-plane of the crystal as illustrated in FIG. 5B, and is generated in portions at the upper left and the lower right of the crystal element 100, and on the other hand, in the case of the crystal element 10 according to this disclosure, the crystal face 100e is generated in portions at the upper right and the lower left of the crystal element 10 unlike Comparative Example as illustrated in FIG. 1C. That is, in the case with the crystal element 10 according to this disclosure, both the end surfaces in the Z′-direction have a structure without the m-plane of the crystal.

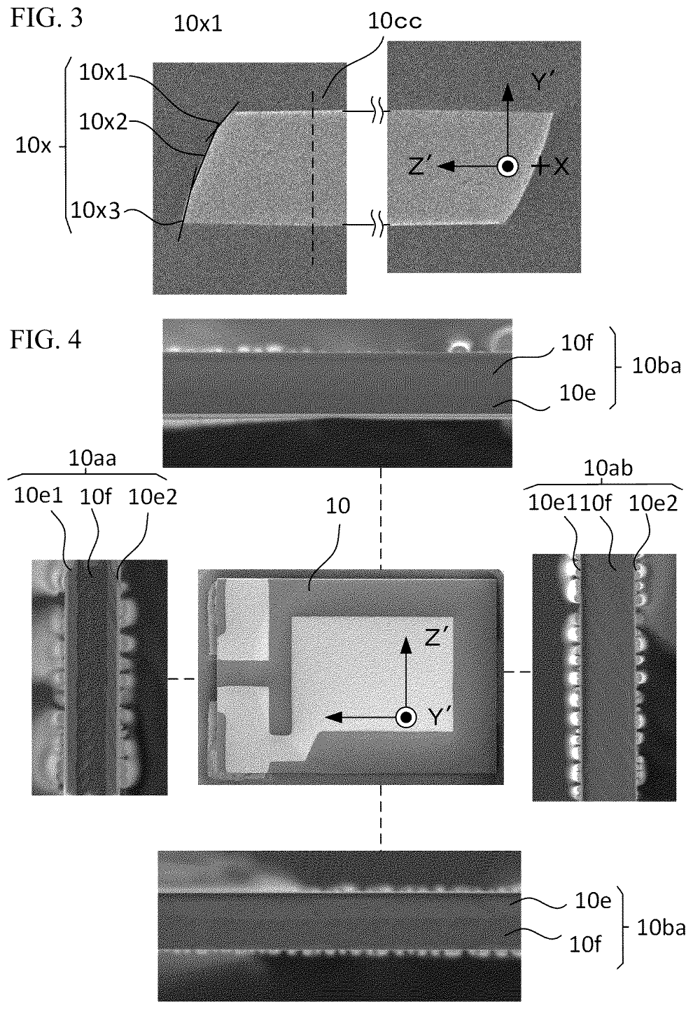

Note that, while the above-described embodiment has described the example in which both the end surfaces along the Z′-axis are the surfaces constituted of the plane 10f having the contour parallel to the normal line of the principal surface of the crystal element 10 and the crystal face 10e, both the end surfaces along the Z′-axis may be constituted of a crystal face 10x derived from the crystal non-parallel to the normal line 10cc of the principal surface of the crystal element 10 as illustrated in FIG. 3 (the SEM photograph) in some cases. The example in FIG. 3 is the example in which the crystal face 10x is constituted of a plurality of, in this case, three crystal faces 10x1, 10x2, and 10x3.

Even when both the end surfaces along the Z′-axis are constituted of the crystal face 10x derived from the crystal non-parallel to the normal line 10cc of the principal surface of the crystal element 10, at least each of the +X-plane and the −X-plane of the crystal element 10 is constituted of the vertical plane 10f, the first crystal face 10e1, and the second crystal face 10e2, and includes the vertical plane 10f, and therefore, the reduction of the vibrating region in the X-axis direction is avoidable. The etching rate for the wet etching between crystallographic axes of the crystal is Z-plane>+X-plane>−X-plane, and therefore, etching easily proceeds on the end surface along the Z′-axis, and the vertical plane is easily lost. However, as long as the vertical plane 10f is present on each of the +X-plane and the −X-plane of the crystal element 10 even when both the end surfaces along the Z′-axis has the lost vertical planes, the lost amount is a small amount even when the vertical planes of the end surfaces along the Z′ are lost, and accordingly, the amount of the inclined surface of the Z′-end surface is less than the conventional case, thereby allowing for less reduction of the vibrating region in the Z′-direction of the crystal element than the conventional case.

With the crystal element 10 of this embodiment, each of the side surfaces 10aa, 10ab, 10ba, and 10bb of the crystal element has the structure including the plane 10f perpendicular to the principal surfaces 10ca and 10cb, which allows for obtaining an effect to expand a region usable for the vibrating region of the crystal element 10 compared with the otherwise case, that is, the case where the inclined surface constitutes the side surface as in the conventional case.

### 1-4. State of Each Side Surface of Crystal Element

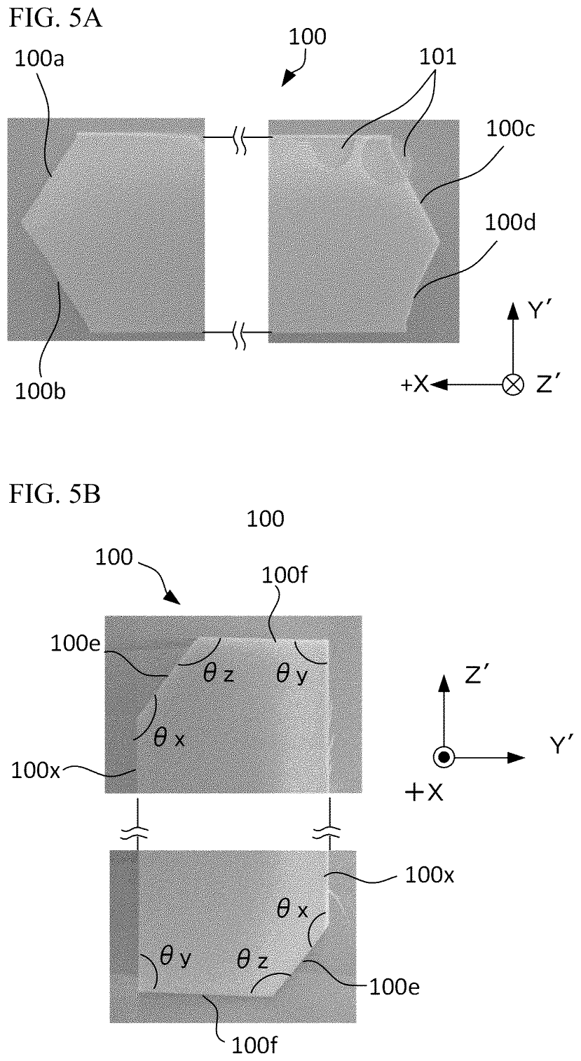

This disclosure has described that the plane having the contour parallel to the normal line of the principal surface of the crystal element is possible in any case of the case of the crystal face, the case of the non-crystal face, or the case of mixture of the crystal face and the non-crystal face. With regard to this, the SEM photographs observing respective side surfaces of the crystal element 10 of the embodiment illustrate structural examples of the respective side surfaces. FIG. 4 illustrates the example thereof. In the case of the crystal element 10 of the embodiment, the respective planes 10f having the contour parallel to the normal line of the principal surface on the side surfaces 10ab, 10ab, 10ba, and 10bb can be inferred to be crystal faces of the crystal.

### 1-5. Shape of Corner Portion of Crystal Element

When four corner portions of the crystal element 10 of the embodiment is focused, the structure is as follows. That is, as illustrated in FIG. 1A, four corner portions 10g, 10h, 10i, and 10j are right-angled corner portions in plan view. The right-angled means an angle formed by intersecting sides is 90±2 degrees, preferably 90±1 degree. When the four corner portions 10g, 10h, 10i, and 10j are right-angled corner portions in plan view, the effect to expand the vibrating region of the crystal element 10 is obtainable compared with the otherwise case, thereby being preferable.

### 1-6. Other Application Examples

While the above-described embodiment has described the example in which this disclosure is applied to the AT-cut crystal element having a flat-plate shape in a quadrilateral shape and being flat in an entire view, this disclosure is applicable to, what is called, a table-top type AT-cut crystal element, which has a vibrator thicker than the other portions, as the crystal element.

This disclosure is also applicable to a twice-rotated crystal element typified by an SC-cut and the like obtained by rotating a surface perpendicular to the Y-axis of the crystal by φ degrees with the Z-axis of the crystal as a rotational center, and furthermore, rotating from this state by θ degrees with the X-axis of the crystal as a rotational center. In such a case, the first axis is the X′-axis derived from the twice rotation, the second axis is the Z′-axis derived from the twice rotation, and the third axis is the Y′-axis derived from the twice rotation.

The first disclosure is also applicable to those other than the thickness-shear mode vibrating piece. For example, the first disclosure is also applicable to a crystal element having a mode of vibration of a contour mode, such as a GT-cut.

### 2. Crystal Element of Comparative Example

To deepen the understanding of the crystal element of the first disclosure, the crystal element 100 of Comparative Example will be described with reference to FIG. 5A and FIG. 5B. That is, FIG. 5A and FIG. 5B relate to the crystal element 100 of Comparative Example manufactured using the ordinary photolithography technique and wet etching technique, and illustrate SEM photographs of the respective surfaces as the result of observing the total of four side surfaces of two side surfaces intersecting with the X-axis of the crystal and two side surfaces intersecting with the Z′-axis of the crystal.

FIG. 5A is a comparative example corresponding to FIG. 1B, and FIG. 5B is a comparative example corresponding to FIG. 1C. In the case with the crystal element 100 of Comparative Example, the two side surfaces intersecting with the X-axis of the crystal (FIG. 5A) are any one of two crystal faces 100a, 100b or 100c, 100d, and are constituted of two inclined crystal faces. Note that, in FIG. 5A, those denoted with the reference numeral 101 are air bubbles occurred in an embedded resin during making of a cross-sectional surface observation material, and are impertinent to this disclosure.

The two side surfaces (FIG. 5B) intersecting with the Z′-axis of the crystal are respectively constituted of the crystal face 100e intersecting with a principal surface 100x of the crystal element 100 at an angle θx and a crystal face 100f intersecting with the principal surface 100x of the crystal element 100 at an angle θy. The crystal face 100e and the crystal face 100f form an angle θz. θx≈143°, θy≈92°, θz≈127°. The crystal face 100e is an m-plane, which is one of the crystal faces of the crystal.

Accordingly, the crystal element 100 of the present disclosure and the crystal element 100 of Comparative Example are different in relation to the end surface shapes.

### 3. Quartz Crystal Device in Embodiment

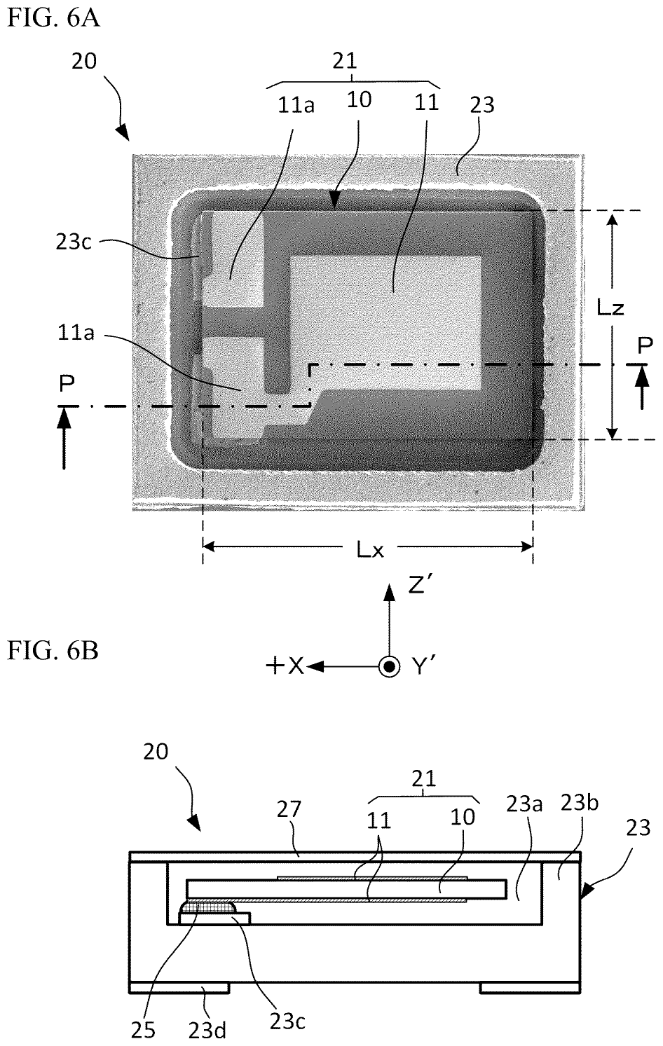

Next, the quartz crystal device 20 of the embodiment will be described with reference to FIG. 6A and FIG. 6B. FIG. 6A and FIG. 6B are explanatory drawings of the crystal unit 20 as the quartz crystal device 20 of the embodiment, and in particular, FIG. 6A is a top view thereof, and FIG. 6B is a sectional drawing of the quartz crystal device 20 taken along the line VIB-VIB in FIG. 6A. However, in FIG. 6A, a lid member 27 included in the quartz crystal device 20 is omitted from illustration. FIG. 6A is an image using an electron microscope (SEM) photograph of the quartz crystal device 20 of the embodiment.

The crystal unit 20 as the quartz crystal device of the embodiment includes a quartz-crystal vibrating piece 21 including the crystal element 10 according to the first disclosure and the excitation electrodes 11 and the extraction electrodes 11a provided on the front and back principal surfaces of the crystal element 10, and a container 23 that contains the quartz-crystal vibrating piece 21.

The container 23 in the case of this example includes a depressed portion 23a in a quadrilateral shape in plan view for housing the quartz-crystal vibrating piece 21, a dike 23b surrounding the depressed portion 23a, an adhesion pad 23c on which the quartz-crystal vibrating piece 21 is fixedly adhered, and an external connection terminal 23d that is provided on an outer bottom surface of the container 23 and connects the quartz crystal device 20 to any electronic equipment. The adhesion pad 23c and the external connection terminal 23d are electrically connected via via-wiring or castellation (not illustrated). This container 23 can be constituted of a known ceramic package.

The quartz-crystal vibrating piece 21 is in a cantilever support structure in this case. The quartz-crystal vibrating piece 21 is connected and fixed on the adhesion pad 23c of the container 23 at the position of the extraction electrode 11a via a conductive adhesive 25. The dike 23b of the container 23 has a top surface on which the lid member 27 is joined in a structure corresponding to the sealing method, and the quartz-crystal vibrating piece 21 is sealed in the container 23.

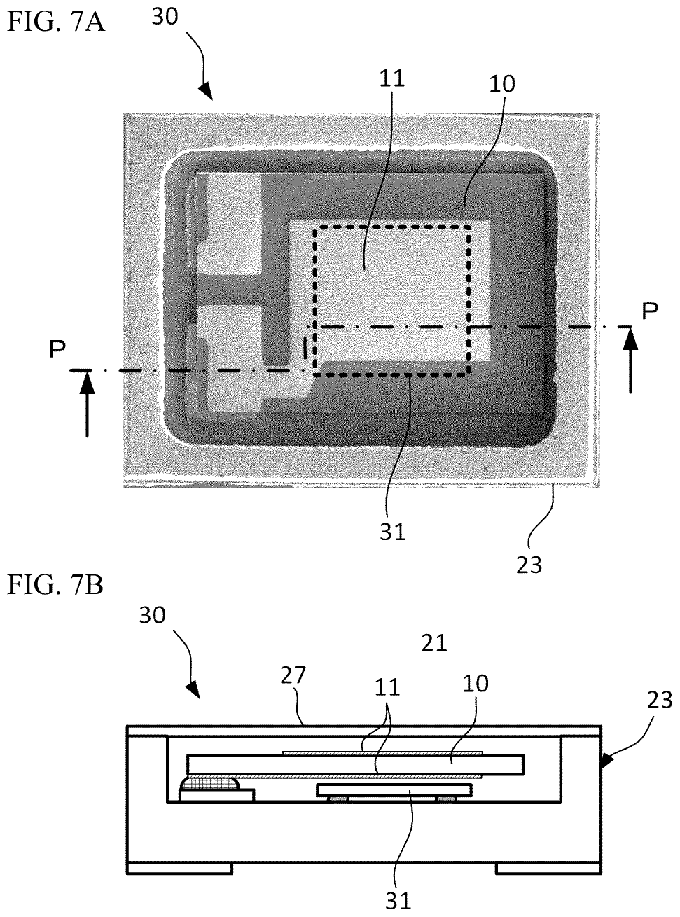

Note that, while the above-described embodiment has described the example of the crystal unit as the quartz crystal device, the quartz crystal device 30 that has the crystal element 10 as illustrated in FIG. 7A and FIG. 7B and another electronic component 31, such as a temperature sensor and an oscillator circuit, mounted in the container 23, that is, a crystal unit with a temperature sensor or a crystal controlled oscillator (also including those with a temperature compensation function) is also included in the quartz crystal device of the present disclosure.

While the one with the structure having the depressed portion 23a as the container 23 has been described, the container 23 may be a container constituted of a flat-plate-shaped base and a cap-shaped lid member having a depressed portion that houses the quartz-crystal vibrating piece.

While the illustration is omitted, an electronic device having a chamber that houses the quartz-crystal vibrating piece and a chamber that houses another electronic component, such as an oscillator circuit, are laminated back to back, and having a cross-sectional surface taken along a laminating direction in, what is called, a H-type structure may be employed.

### 4. Examination of Electrical Performance

### 4-1. Example and Comparative Example

In order to further deepen the understanding of the present disclosure, a plurality of crystal units for Example and a plurality of crystal units for Comparative Example described below were prototyped, and respective electrical performances were measured, and thus, differences and the like between the two were examined.

As the crystal units for Example, the crystal unit 20 illustrated in FIG. 6A and FIG. 6B were prototyped using the crystal element 10 having the end surface on the +X-side and the −X-side end surface, and both the end surfaces along Z′ in the structure described above using FIG. 1B and FIG. 1C. That is, the crystal unit 20 was prototyped using the crystal element 10 in which all the end surfaces have the vertical planes remaining. In contrast to this, as the crystal units for Comparative Example, crystal units having the structure in FIG. 6A and FIG. 6B were prototyped similarly to Example except that the crystal elements 100 described using FIG. 5A and FIG. 5B and having excitation electrodes formed on the front and back principal surfaces were used.

Note that the crystal elements in Example and Comparative Example have the same outside dimensions, but have the end surface structures different from one another as described above. That is, in the case of Example, the end surfaces have the vertical planes. All the crystal elements of Example and Comparative Example had frequencies of 76.8 MHz in this case. Surely, the frequencies are one example, and are not limited to this.

The crystal elements of Example and Comparative Example have the different end surface shapes as described above, the dimensions of the portions as the inclined surfaces on the end surfaces are different as described below. That is, in the case with the crystal element 10 according to Example, a dimension X1 of the inclined portion on the +X-side end surface illustrated in FIG. 1B was 3.3 μm, a dimension X2 of the inclined portion on the −X-side end surface illustrated in FIG. 1B was 1.1 μm, a dimension Z1 of one inclined portion of the inclined portions at both the ends along the Z′-axis illustrated in FIG. 1C was 4.0 μm, and a dimension Z2 of the other inclined portion was 3.5 μm. Accordingly, in the case of the crystal element 10 of Example, the sum of the dimensions of the inclined portions at both the ends along the X-direction is 3.3+1.1=4.4 μm, and the sum of the dimensions of the inclined portions at both the ends along the Z′-axis is 4.0+3.5=7.5 μm.

In contrast to this, in the case of the crystal element 100 of Comparative Example, dimensions corresponding to the above-described X1 and X2 were 6.6 μm and 4.9 μm, and dimensions corresponding to the above-described Z1 and Z2 were 7.5 μm and 6.1 μm. Accordingly, in the case of the crystal element 100 of Comparative Example, the sum of the dimensions of the inclined portions at both the ends along the X-direction is 6.6+4.9=11.5 μm, and the sum of the dimensions of the inclined portions at both the ends along the Z′-axis is 7.5+6.1=13.6 μm.

Accordingly, when the dimensions of the inclined portions of the crystal element 10 of Example and the crystal element of Comparative Example are compared with Comparative Example used as a criteria, 4.4/11.5≈0.38 for the X-direction and 7.5/13.6≈0.55 for the Z′-direction. Accordingly, the dimension of the inclined portion in the X-direction of the crystal element 10 of Example is 38% that is a small dimension with respect to the same dimension of Comparative Example, and the dimension of the inclined portion in the Z′-direction of the crystal element 10 of Example is 55% that is a small dimension with respect to the same dimension of Comparative Example. Accordingly, compared with Comparative Example, Example has a wide principal surface, that is, a wide region usable for the vibrating region.

While the difference between the above-described inclined portion dimensions may be considered to be a small amount, the difference is considered to be of valuable as the quartz crystal device becomes smaller and smaller and the planar shape of the crystal element becomes smaller and smaller. From the view point of making a plurality of the crystal elements in a crystal wafer, the number of crystal elements made in one wafer can also be expected to possibly be increased.

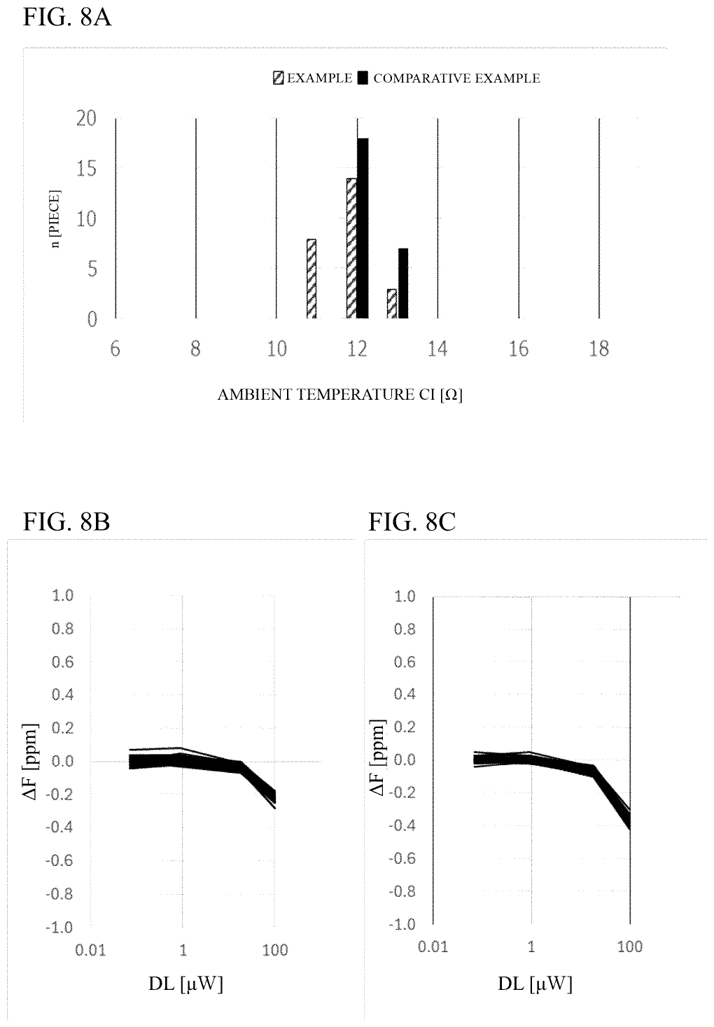

Next, crystal impedances (CI) of the crystal units of Example and Comparative Example prototyped above at ordinary temperature were measured. Drive level characteristics of the crystal units of Example and Comparative Example, that is, frequency variation degrees of the crystal units when the electric power to drive the respective crystal units are changed were measured. FIG. 8A is a histogram illustrating CI distributions of the crystal units of Example and Comparative Example at ordinary temperature. FIG. 8B is a drawing illustrating respective frequency change rates (ppm) when the electric power is applied of the crystal units of Example and Comparative Example with respect to the initial electric power when the drive level (W) is changed.

From the CI distributions in FIG. 8A, it can be seen that the CI of the crystal unit of Example is as good as or slightly better than that of the crystal unit of Comparative Example. From the drive level characteristics in FIG. 8B, it can be seen that the drive level characteristics of the crystal unit of Example is as good as or slightly better than that of the crystal unit of Comparative Example.

Accordingly, it is allowed to say that the crystal element of the present disclosure is effective for characteristic improvement of the quartz crystal device and effective for avoiding the reduced vibrating region of the crystal element.

### 4-2. Examination Example of Dimensions of Crystal Element in 76.8 MHZ Product

A crystal unit (including those with a built-in thermistor) with an oscillation frequency of 76.8 MHz is, for example, effective as a reference transmitting source of various kinds of electronic equipment, such as a mobile phone. In view of this, there has been examined electrical performances of the crystal unit with the oscillation frequency of 76.8 MHz and dimension ranges of an AT-cut quartz-crystal vibrating piece preferable for mass production, that is, respective preferable ranges of an X-dimension that is a dimension along the X-axis of the crystal, and a Z-dimension that is a dimension along the Z′-axis of the crystal. The results thereof are described below.

The inventor of this application prototyped the quartz crystal devices 20 illustrated in FIG. 6A and FIG. 6B, that are, the crystal units 20 using the crystal elements 10 illustrated in FIG. 1A to FIG. 1C, and having a dimension Lx along the X-axis of the crystal and a dimension Lz along the Z′-axis of the crystal (see FIG. 6A) in a plurality of dimensions as below.
Lx (unit: mm): five levels of 0.7391, 0.7416, 0.7441, 0.7446, and 0.7491
Lz (unit: mm): nine levels of 0.5035, 0.506, 0.5085, 0.511, 0.5135, 0.516, 0.5185, 0.521, and 0.5235

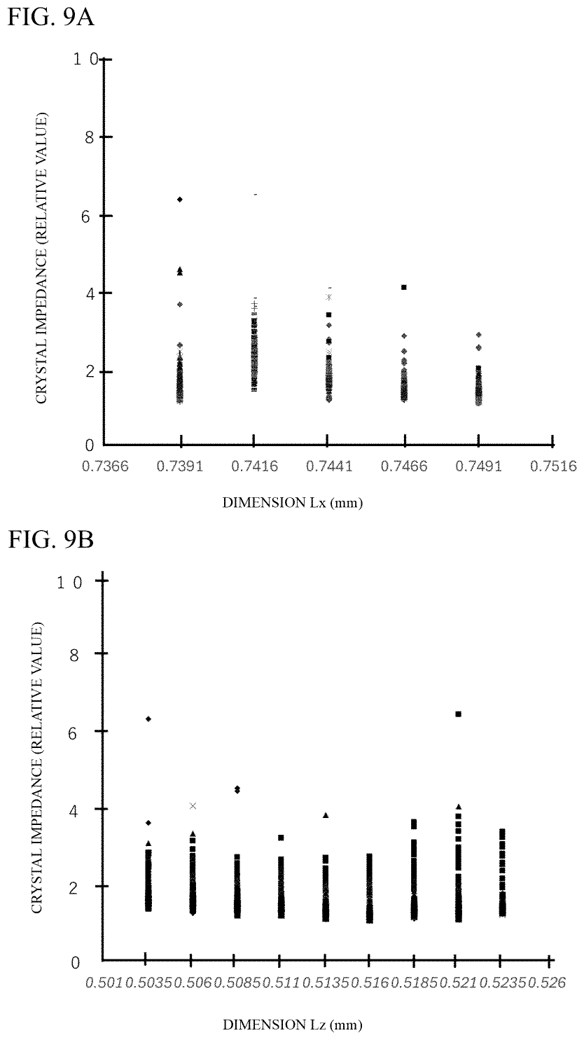

Respective crystal impedances (CI) of the quartz crystal devices prototyped in these dimensions were measured. FIG. 9A and FIG. 9B illustrate summaries of the results of this measurement. FIG. 9A illustrates CI distributions of the respective prototypes with the dimension Lx on the horizontal axis and the CI (relative value) on the vertical axis. FIG. 9B illustrates CI distributions of the respective prototypes with the dimension Lz on the horizontal axis and the CI (relative value) on the vertical axis. Specifically, in the case with FIG. 9A, plots of the respective dimensions Lx in the vertical direction in the drawing are respective CI distributions of the prototypes having dimensions Lz differing with respect to the dimensions Lx, and in the case with FIG. 9B, plots of the respective dimensions Lz in the vertical direction in the drawing are respective CI distributions of the prototypes having Lx differing with respect to the dimensions Lz. The specifications of the CI for the prototypes of this time may be 4 or less in a relative value, and is preferably 3.5 or less.

From FIG. 9A and FIG. 9B, the ranges of the prototypes of this time were roughly in a preferable range. However, if it must be said, it is said the dimensions larger than 0.739 mm is preferred for the dimension Lx within the range of the prototypes this time from FIG. 9A. From FIG. 9B, it is said that there is a local minimum range of the CI near Lz=0.511 mm to 0.516 mm for the dimension Lz within the range of the prototypes of this time.

The following table is the measurement results of the CIs described above summarized from a different point of view. This table is a table illustrating to which level average values of the CIs of the prototypes for each combination of the dimension Lx and the dimension Lz correspond when they are compared with an average value Avg and a standard deviation a of the CIs of the whole prototypes described above after calculating the average value Avg and the standard deviation a of the CIs of the whole prototypes described above, and calculating the respective average values of the CIs of the prototypes for each combination of the dimension Lx and the dimension Lz. The cell attached with Avg in each of the cells in the table means a level indicating a CI of the equal level to the average value Avg of the CIs of the whole prototypes. The cell attached with +0.5σ in each of the cells in the table means a level indicating a CI of a +0.5σ level with respect to the average value Avg of the CIs of the whole prototypes. The cell attached with −0.5σ in each of the cells in the table means a level indicating a CI of a −0.5σ level with respect to the average value Avg of the CIs of the whole prototypes. Hereinafter, the same meanings apply to . . . +1.5σ . . . −1.5σ and the like.

Examining FIG. 9A and FIG. 9B, and the table below, it is allowed to say that one example of the preferable size of the AT-cut crystal element with the oscillation frequency of 76.8 MHz has the dimension Lx along the X-axis of the crystal and the dimension Lz along the Z′-axis of the crystal of
0.7391 mm<Lx≤0.7491 mm, and
0.5035 mm≤Lz≤0.5235 mm.
   This is allowed to say that
40.61<Lx/crystal element thickness≤41.15, and
27.66≤Lz/crystal element thickness≤28.76
   when described in a ratio (what is called an aspect ratio) to a thickness 0.0182 mm of the AT-cut crystal element with the oscillation frequency of 76.8 MHz.

More preferably, Lx and Lz are said to preferably be
0.7416 mm<Lx≤0.7491 mm, and
0.5035 mm≤Lz≤0.5235 mm

Note that while the preferable dimension Example of the AT-cut crystal element of the product with the oscillation frequency of 76.8 MHz have been examined above, the above-described dimension ranges are considered to also be applicable to an AT-cut crystal element with another oscillation frequency close to 76.8 MHz, for example, an oscillation frequency of approximately 76.8±1 MHz. In such a case, the dimensions Lx and Lz may be slightly displaced with respect to the above-described range, but in such a case, the range obtained by correcting the above-described Lx and Lz by the aspect ratio as a ratio of the thickness of the crystal element to the dimension Lx or Lz is simply used.

| | | Dimension Lz | | | | | | | | |
|---|---|---|---|---|---|---|---|---|---|---|
| | | 0.5035 | 0.506 | 0.5085 | 0.511 | 0.5135 | 0.516 | 0.5185 | 0.521 | 0.5235 |
| Dimension Lx | 0.7391 | +0.5σ | −0.5σ | +0.5σ | −0.5σ | +1.50 | −σ | −σ | −σ | −σ |
| | 0.7416 | +0.5σ | +0.5σ | +0.5σ | +0.5σ | +0.5σ | +0.5σ | +1.5σ | +1.5σ | +σ |
| | 0.7441 | Avg | Avg | −0.5σ | Avg | Avg | −0.5σ | −0.5σ | −0.5σ | +0.5σ |
| | 0.7466 | −0.5σ | −0.5σ | −σ | −σ | −σ | −σ | −σ | −σ | −σ |
| | 0.7491 | −0.5σ | −0.5σ | −σ | −σ | −1.5σ | −1.5σ | −σ | −σ | −σ |

### 5. Exemplary Method for Manufacturing Crystal Element 10 and Intermediate Wafer for Forming Quartz Crystal Device

Next, one example of a method for manufacturing the crystal element 10 of the first disclosure with reference to FIG. 10A to FIG. 10D (an embodiment of a fourth disclosure) and an embodiment of the intermediate wafer for the quartz crystal device as a third disclosure will be described. FIG. 10A to FIG. 10D are relevant portions of the manufacturing process flowchart therefor. Note that FIG. 10B and FIG. 10C are sectional drawings taken along the line XB-XB of FIG. 10A.

First, an AT-cut crystal wafer 50 is prepared (FIG. 10A). Next, a laser light, preferably, an ultrashort pulse laser irradiates an outer edge planned portion 50a along the outer edge planned portion 50a of the crystal element 10 of this crystal wafer 50 to form a crystallinity lost region 50b that runs along a thickness direction of the crystal wafer in the outer edge planned portion 50a (FIG. 10B). Note that, during the laser irradiation, the laser does not irradiate a portion 50c (see FIG. 10A) that connects each crystal element 10 to the crystal wafer 50. Since the laser irradiation forms the crystallinity lost region 50b, a width W (see FIG. 10B) of the crystallinity lost region 50b is allowed to be narrow, thereby being able to obtain an effect of increasing the number of the crystal elements 10 in the crystal wafer 50.

The crystal wafer in which the crystallinity lost region 50b is formed is immersed in an etchant for wet etching, for example, a hydrofluoric acid-based etchant (not illustrated), the region including the outer edge planned portion of the crystal wafer is removed and the crystal wafer is penetrated, and respective outer shapes of the crystal elements 10 are formed (FIG. 10C).

In this etching process, the etching of the crystallinity lost region 50b of the crystal wafer 50 proceeds quickly compared with the crystalline region. Accordingly, compared with the ordinary manufacturing method that uses the photolithography technique and the wet etching technique, the shortened etching time is achieved. During the above-described wet etching, the proximity of the surface of the crystal wafer 50 is etched in a direction intersecting with the thickness direction of the crystal wafer 50, and the crystal face 10e is generated. The dimension of the crystal face 10e varies by a length of the above-described etching time. On the other hand, the surface (the plane 10f (the vertical plane 10f) illustrated in FIG. 1A and the like) parallel to the normal line of the principal surface of the crystal wafer becomes the vertical plane 10f with the crystallinity lost region remaining when the wet etching time is short, and becomes the vertical plane 10f with the crystal face of the crystal generated while maintaining the vertical plane when the wet etching time is appropriate. When the wet etching time is long, the inclined crystal face with the lost vertical plane 10f is generated. However, since the object of the present disclosure is to form the vertical plane 10f on the side surface of the crystal element, the wet etching is performed according to the time with which the vertical plane remains. This allows for obtaining the crystal wafer including a plurality of the crystal elements having the planes 10f with the contour 10fa parallel to the normal line of the principal surface 10c of the crystal element 10.

As can be seen from the above, adjusting the time of immersing the crystal wafer in which the crystallinity lost region 50b is formed in the etchant for wet etching allows for controlling a proportions of the dimension of the vertical plane 10f in the thickness direction of the crystal wafer (the dimension denoted with t1 in FIG. 1A and the like) and the crystal face derived from the crystal connecting to the vertical plane.

Next, the excitation electrodes 11 are formed on the front and back of the respective crystal elements 10 by a patterning technique according to known film forming technique and photo lithography technique. These processes allow for forming an intermediate wafer 50x for forming the quartz crystal device. That is, the crystal wafer 50x that includes the plurality of crystal elements 10 including the excitation electrodes 11 on the front and back principal surfaces in a matrix is formable (FIG. 10D). Thereafter, for example, a dividing process by a known dicing technique is performed on this crystal wafer 50x, thus obtaining the crystal element 10 illustrated in FIG. 1A to FIG. 1C. Note that the individualization of the crystal elements from the crystal wafer may be performed by preliminarily providing grooves (not shown) for snapping in connection portions between the crystal elements and a frame of the crystal wafer 50y, and snapping off the crystal elements from the crystal wafer using these grooves as a starting point.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A crystal element in a quadrilateral shape in plan view having a first axis-second axis plane specified by a first axis derived from an X-axis of a crystal and a second axis derived from a Z-axis of the crystal as a principal surface and having a third axis derived from a Y-axis of the crystal as a thickness direction, wherein
when one side of side surfaces intersecting with the first axis of the crystal element is defined as a first side surface of the first axis and another side is defined as a second side surface of the first axis, and one side of side surfaces intersecting with the second axis of the crystal element is defined as a first side surface of the second axis and another side is defined as a second side surface of the second axis,
the first side surface of the first axis and the second side surface of the first axis are each constituted of a crystal face derived from the crystal and a plane that has a contour parallel to a normal line of the principal surface, and
the first side surface of the second axis and the second side surface of the second axis are each constituted of a crystal face derived from the crystal and a plane that has a contour parallel to a normal line of the principal surface, or constituted of a crystal face derived from the crystal non-parallel to the normal line of the principal surface.

2. The crystal element according to claim 1, wherein
when a thickness of the crystal element is t and a length of the plane that has the contour parallel to the normal line along the third axis is t1, t1/t≥0.5.

3. The crystal element according to claim 1, wherein
the crystal face has one end including a crystal face continuing one principal surface of front and back principal surfaces of the crystal element and one end including a crystal face continuing another principal surface of the front and back principal surfaces of the crystal element.

4. The crystal element according to claim 1, wherein
the crystal face has one end including a crystal face continuing one principal surface of front and back principal surfaces of the crystal element, one end including a crystal face continuing another principal surface of the front and back principal surfaces of the crystal element and further yet another crystal face.

5. The crystal element according to claim 1, wherein
the crystal element is an AT-cut crystal element,
the first axis is the X-axis of the crystal,
the second axis is a Z′-axis displaced from the Z-axis of the crystal due to a cut angle of the AT-cut, and
the third axis is a Y′-axis displaced from the Y-axis of the crystal due to the cut angle of the AT-cut.

6. The crystal element according to claim 1, wherein
the crystal element is an AT-cut crystal element,
the first axis is the X-axis of the crystal,
the second axis is a Z′-axis displaced from the Z-axis of the crystal due to a cut angle of the AT-cut,
the third axis is a Y′-axis displaced from the Y-axis of the crystal due to the cut angle of the AT-cut,
the first side surface of the second axis and the second side surface of the second axis are each constituted of the crystal face derived from the crystal and the plane that has the contour parallel to the normal line of the principal surface, and
the crystal faces derived from the crystal generated on the first side surface and the second side surface of the second axis are crystal faces generated on a side of the principal surface on an opposite side of a side of the principal surface on which an m-plane of the principal surface is allowed to be generated, the m-plane being one of crystal faces of the crystal.

7. The crystal element according to claim 1, wherein
the crystal element is an AT-cut crystal element,
the first axis is the X-axis of the crystal,
the second axis is a Z′-axis displaced from the Z-axis of the crystal due to a cut angle of the AT-cut,
the third axis is a Y′-axis displaced from the Y-axis of the crystal due to the cut angle of the AT-cut, and
the planes having the contour parallel to the normal line included in the respective side surfaces at both ends along the X-axis have rough surfaces.

8. The crystal element according to claim 1, wherein
the crystal element is an AT-cut crystal element,
the first axis is the X-axis of the crystal,
the second axis is a Z′-axis displaced from the Z-axis of the crystal due to a cut angle of the AT-cut,
the third axis is a Y′-axis displaced from the Y-axis of the crystal due to the cut angle of the AT-cut,
a cross-sectional surface taken along an X-Y′ plane determined by the X-axis and the Y′-axis of the crystal element includes the plane having the contour parallel to the normal line, and a first crystal face and a second crystal face connected to the plane having the contour parallel to the normal line at a plus-side end portion of the X-axis, and
when an angle formed by the plane having the contour parallel to the normal line and the first crystal face is defined as θa and an angle formed by the plane having the contour parallel to the normal line and the second crystal face is defined as θb,
$$114 ° \leq θ a \leq 130 ° , 114 ° \leq θ b \leq 130 ° .$$

9. The crystal element according to claim 1, wherein
the crystal element is an AT-cut crystal element,
the first axis is the X-axis of the crystal,
the second axis is a Z′-axis displaced from the Z-axis of the crystal due to a cut angle of the AT-cut,
the third axis is a Y′-axis displaced from the Y-axis of the crystal due to the cut angle of the AT-cut,
a cross-sectional surface taken along an X-Y′ plane determined by the X-axis and the Y′-axis of the crystal element includes the plane having the contour parallel to the normal line, and a first crystal face and a second crystal face connected to the plane having the contour parallel to the normal line at a minus-side end portion of the X-axis, and
when an angle formed by the plane having the contour parallel to the normal line, and the first crystal face is defined as θc and an angle formed by the plane having the contour parallel to the normal line and the second crystal face is defined as θd,
$$149 ° \leq θ c \leq 158 ° , 149 ° \leq θ d \leq 158 ° .$$

10. The crystal element according to claim 1, wherein
the crystal element is an AT-cut crystal element,
the first axis is the X-axis of the crystal,
the second axis is a Z′-axis displaced from the Z-axis of the crystal due to a cut angle of the AT-cut,
the third axis is a Y′-axis displaced from the Y-axis of the crystal due to the cut angle of the AT-cut,
a cross-sectional surface taken along a Y′-Z′ plane determined by the Y′-axis and the Z′-axis of the crystal element includes the plane having the contour parallel to the normal line and a crystal face connected to the plane having the contour parallel to the normal line at both end portions in the Z′-axis direction, and
when an angle formed by the plane having the contour parallel to the normal line and the crystal face at one end portion in the Z′-axis direction is defined as θe, and an angle formed by the plane having the contour parallel to the normal line and
the crystal face at another end portion in the Z′-axis direction is defined as θf,
$$141 ° \leq θ e \leq 162 ° , 141 ° \leq θ f \leq 162 ° .$$

11. The crystal element according to claim 1, wherein
the crystal element is an AT-cut crystal element,
the first axis is the X-axis of the crystal,
the second axis is a Z′-axis displaced from the Z-axis of the crystal due to a cut angle of the AT-cut,
the third axis is a Y′-axis displaced from the Y-axis of the crystal due to the cut angle of the AT-cut,
a cross-sectional surface taken along an X-Y′ plane determined by the X-axis and the Y′-axis of the crystal element includes the plane having the contour parallel to the normal line, and a first crystal face and a second crystal face connected to the plane having the contour parallel to the normal line at a plus-side end portion of the X-axis, and
when an angle formed by the plane having the contour parallel to the normal line and the first crystal face is defined as θa and an angle formed by the plane having the contour parallel to the normal line and the second crystal face is defined as θb,
$$114 ° \leq θ a \leq 130 ° , 114 ° \leq θ b \leq 130 ° ,$$
the cross-sectional surface taken along the X-Y′ plane determined by the X-axis and the Y′-axis of the crystal element includes the plane having the contour parallel to the normal line, and a first crystal face and a second crystal face connected to the plane having the contour parallel to the normal line at a minus-side end portion of the X-axis, and
when an angle formed by the plane having the contour parallel to the normal line and the first crystal face is defined as θc and an angle formed by the plane having the contour parallel to the normal line and the second crystal face is defined as θd,
$$149 ° \leq θ c \leq 158 ° , 149 ° \leq θ d \leq 158 ° ,$$
a cross-sectional surface taken along a Y′-Z′ plane determined by the Y′-axis and the Z′-axis of the crystal element includes the plane having the contour parallel to the normal line and a crystal face connected to the plane having the contour parallel to the normal line at both end portions in the Z′-axis direction, and
when an angle formed by the plane having the contour parallel to the normal line and the crystal face at one end portion in the Z′-axis direction is defined as θe, and
an angle formed by the plane having the contour parallel to the normal line and the crystal face at another end portion in the Z′-axis direction is defined as θf,
$$141 ° \leq θ e \leq 162 ° , 141 ° \leq θ f \leq 162 ° .$$

12. The crystal element according to claim 1, wherein
the crystal element is a twice-rotated crystal element obtained by rotating a surface perpendicular to the Y-axis of the crystal by φ degree with the Z-axis of the crystal used as a rotational center, and furthermore, by θ degree with the X-axis of the crystal used as a rotational center from the state,
the first axis is an X′-axis derived from the twice rotation,
the second axis is a Z′-axis derived from the twice rotation, and
the third axis is a Y′-axis derived from the twice rotation.

13. A crystal element in a quadrilateral shape in plan view having a first axis-second axis plane specified by a first axis derived from an X-axis of a crystal and a second axis derived from a Y-axis of the crystal as a principal surface and having a third axis derived from a Z-axis of the crystal as a thickness direction, wherein
when one side of side surfaces intersecting with the first axis of the crystal element is defined as a first side surface of the first axis and another side is defined as a second side surface of the first axis, and one side of side surfaces intersecting with the second axis of the crystal element is defined as a first side surface of the second axis and another side is defined as a second side surface of the second axis,
the first side surface of the first axis, the second side surface of the first axis, the first side surface of the second axis, and the second side surface of the second axis are each constituted of a crystal face derived from the crystal and a vertical plane as a plane that has a contour parallel to a normal line of the principal surface.

14. The crystal element according to claim 1, wherein
the crystal element is an AT-cut crystal element having an oscillation frequency close to 76.8 MHz,
the first axis is the X-axis of the crystal
the second axis is a Z′-axis displaced from the Z-axis of the crystal due to a cut angle of the AT-cut,
the third axis is a Y′-axis displaced from the Y-axis of the crystal due to the cut angle of the AT-cut,
when a dimension of the crystal element along the X-axis is defined as Lx, and a dimension along the Z′-axis is defined as Lz,
Lx and Lz are
$$0.7391 mm < Lx \leq 0.7491 mm ,$$
$$0.5035 mm \leq Lz \leq 0.5 \; 235 mm .$$

15. The crystal element according to claim 1, wherein
four corner portions of the crystal element in the quadrilateral shape are right-angled corner portions in plan view.

16. A quartz crystal device comprising:
a quartz-crystal vibrating piece including the crystal element according to claim 1 and excitation electrodes provided on front and back principal surfaces of the crystal element; and
a container containing the quartz-crystal vibrating piece.

17. A quartz crystal device comprising:
a quartz-crystal vibrating piece including the crystal element according to claim 1 having four corner portions that are right-angled corner portions in plan view and excitation electrodes provided on front and back principal surfaces of the crystal element; and
a container containing the quartz-crystal vibrating piece.

18. A quartz crystal device comprising:
a quartz-crystal vibrating piece including the crystal element according to claim 1 and excitation electrodes provided on front and back principal surfaces of the crystal element; and
a container containing the quartz-crystal vibrating piece, wherein
the quartz crystal device is a crystal unit, a crystal unit with a temperature sensor, or a crystal controlled oscillator.

19. A quartz crystal device comprising:
a quartz-crystal vibrating piece including the crystal element according to claim 1 having four corner portions that are right-angled corner portions in plan view and excitation electrodes provided on front and back principal surfaces of the crystal element; and
a container containing the quartz-crystal vibrating piece, wherein
the quartz crystal device is a crystal unit, a crystal unit with a temperature sensor, or a crystal controlled oscillator.

20. An intermediate wafer for a quartz crystal device made of a crystal wafer comprising
a plurality of quartz-crystal vibrating pieces including the crystal element according to claim 1 and excitation electrodes provided on front and back of the crystal element in a matrix.

21. An intermediate wafer for a quartz crystal device made of a crystal wafer comprising
a plurality of quartz-crystal vibrating pieces including the crystal element according to claim 1 having four corner portions that are right-angled corner portions in plan view and excitation electrodes provided on front and back of the crystal element in a matrix.

22. A method for manufacturing a crystal element, upon manufacturing the crystal element according to claim 1, comprising:
preparing a crystal wafer;
forming a crystallinity lost region in a thickness direction of the crystal wafer by a laser light irradiating an outer edge planned portion along the outer edge planned portion of the crystal element of the crystal wafer; and
forming an outer shape of the crystal element by immersing the crystal wafer in which the crystallinity lost region is formed in an etchant for wet etching and removing a predetermined amount of a region including the outer edge region of the crystal wafer.

23. The method for manufacturing the crystal element according to claim 22, wherein
a time of immersing the crystal wafer in the etchant is adjusted to control a dimension along the normal line of the plane that has the contour parallel to the normal line of the principal surface.
